(19) United States
(12) Patent Application Publication
(10) Pub. No.: US 2011/0240118 A1
(43) Pub. Date: Oct. 6, 2011

(54) METHOD AND DEVICE FOR SCRIBING A THIN FILM PHOTOVOLTAIC CELL

(76) Inventor: Paul Hanlon James Beatty, Placerville, CA (US)

(21) Appl. No.: 13/079,798

(22) Filed: Apr. 4, 2011

Related U.S. Application Data
(60) Provisional application No. 61/320,319, filed on Apr. 2, 2010.

(51) Int. Cl. H01L 31/0224; H01L 31/0272; C23C 14/34

(52) U.S. Cl. 136/256; 438/95; 204/192.12; 257/E31.008

(57) ABSTRACT

The present invention is a method for scribing a thin film solar cell that includes a soda lime glass substrate, a film of molybdenum (Mo), a film of copper indium gallium diselenide (GIGS), a buffering layer, a layer of zinc oxide (i-ZnO), a layer of aluminum doped zinc oxide (n-ZnO:Al or AZO), a first scribe, a conductive link and a second scribe. The method steps include producing the first scribe on the Mo film, depositing the CICS film, the buffering layer and the zinc oxide layer onto the Mo film, producing the second scribe on the CICS film, the zinc oxide layer and the buffering layer above the Mo film, depositing and filling a first insulating material into the first scribe. and depositing a second insulating material that covers the solar cell while filling the first scribe forming a conduction layer.

This application claims priority to U.S. Provisional Application 61/320,319 filed on Apr. 2, 2010, the entire disclosure of which is incorporated by reference.

### TECHNICAL FIELD & BACKGROUND

Solar cells can use thin film semiconductors to absorb sunlight and generate electron hole pairs. A p-n junction can separate out these pairs to generate electricity utilizing a bottom and a top thin film electrode. An example of this type of p-n junction involves utilizing copper indium gallium diselenide (CIGS) as an absorber, a transparent conducting oxide such as n-ZnO:Al as a negative top electrode and molybdenum (Mo) as a bottom positive electrode. Usually, each cell is connected ‘monolithically’ to its neighbor to achieve a higher output voltage utilizing a transparent conducting oxide such as n-ZnO:Al, also known as aluminum doped zinc oxide or AZO. To assemble the cell, three scribes are required, a P1 scribe, separating the Mo between each cell, a P2 scribe disposed on the CIGS film above the Mo, and a P3 scribe disposed on all films above the Mo. This type of solar cell has a number of disadvantages that include the deposition of the film stack is interrupted to manufacture the scribes, the yields can be low, and light-gathering space is wasted in the combined width of the scribes.

### SUMMARY OF THIS INVENTION

In one embodiment of the present invention, all films except the top AZO film are deposited without scribing into the cells and can include sputtering a sulfide onto the film such as cadmium sulfide or zinc sulfide. The P1 scribe is made through all the films and is adjacent to the P2 scribe through the films above the Mo. A thin layer of an insulator, such as a polyimide, is deposited over the P1 scribe that is favorably utilizing the printing. A second film of AZO or some other conductor is vacuum deposited to cover the top surface and only one side wall of the P2 scribed films, which also covers part of the Mo exposed by the P2 scribe. In this embodiment, there is no need for a P3 scribe to isolate the AZO top window electrode between the adjacent cells. The yield is thereby improved due to relatively poor scribing and cell power is increased by avoiding wasted space of an otherwise present P3 scribe.

In one embodiment of the present invention, cell power efficiency is increased by avoiding an electrical shunt path between cells at the P1 scribe. Also, the edge of the p-n junction near the top of the CIGS film is not short-circuited by a conductive electrode material such as AZO.

In one embodiment of the present invention, a conductive link such as silver is deposited on the conductive path between the cells and scribing is done after all the films are deposited. This avoids breaking a vacuum in the deposition of i-ZnO and the AZO without the need for directional deposition of AZO.

### BRIEF DESCRIPTION OF THE DRAWINGS

The present invention will be described by way of exemplary embodiments, but not limitations, illustrated in the accompanying drawing in which like references denote similar elements, and in which:

FIG. 1 illustrates a side perspective view of a solar cell, in accordance with one embodiment of the present invention.

FIG. 2A illustrates a side perspective view of a solar cell, in accordance with one embodiment of the present invention.

FIG. 2B illustrates a side perspective view of a solar cell that includes a deposited P1 scribe, in accordance with one embodiment of the present invention.

FIG. 2C illustrates a side perspective view of a solar cell that includes a P1 scribe being filled with an insulating layer, in accordance with one embodiment of the present invention.

FIG. 2d illustrates a side perspective view of a solar cell after a conduction layer is deposited directionally into a P2 scribe, in accordance with one embodiment of the present invention.

FIG. 3 illustrates a side perspective view of collimated sputtering as a pass-by mode depositing conducting material within a P2 scribe of a vacuum chamber, in accordance with one embodiment of the present invention.

FIG. 4 illustrates a side perspective view of a solar cell with a conductive link, in accordance with one embodiment of the present invention.

FIG. 5 illustrates a flow chart of a method for scribing a thin film cell that includes a soda lime glass substrate, a film of molybdenum (Mo), a film of copper indium gallium diselenide (GIGS), a buffering layer, a layer of zinc oxide (i-ZnO), a layer of aluminum doped zinc oxide (n-ZnO:Al or AZO), a first scribe, and a second scribe, in accordance with one embodiment of the present invention.

FIG. 6 illustrates a flow chart of a method for receiving a deposited conducting material on a thin film solar cell that includes a soda lime glass substrate, a first scribe to receive said deposited insulating material, a sputtering target and a plurality of collimating plates, in accordance with one embodiment of the present invention.

FIG. 7 illustrates a flow chart of a method for scribing a thin film solar cell that includes a soda lime glass substrate, a film of molybdenum (Mo), a film of copper indium gallium diselenide (CICS), a buffering layer, a layer of zinc oxide (i-ZnO), a layer of aluminum doped zinc oxide (n-ZnO:Al or AZO), an insulating layer, a first scribe, a second scribe and a conductive link between any layers or films, in accordance with one embodiment of the present invention.

### DETAILED DESCRIPTION OF ILLUSTRATIVE EMBODIMENTS

Various aspects of the illustrative embodiments will be described utilizing terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is utilized repeatedly. The phrase generally does not refer to the same embodiment, however, it may. The terms “comprising”, “having” and “including” are synonymous, unless the context dictates otherwise.

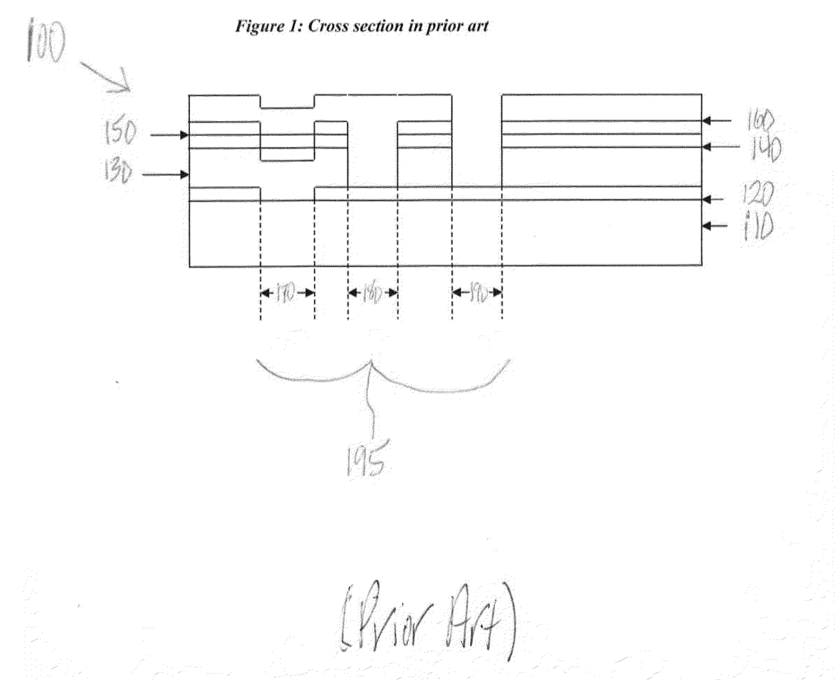

FIG. 1 illustrates a side perspective view of a solar cell 100, in accordance with one embodiment of the present invention. The solar cell 100 includes a soda lime glass substrate 110, a film of molybdenum (Mo) 120, a film of copper indium gallium diselenide (CIGS) 130, a buffering layer 140, a layer of zinc oxide (i-ZnO) 150, a layer of aluminum doped zinc oxide (n-ZnO:Al or AZO) 160, a P1 scribe 170, a P2 scribe 180 and a P3 scribe 190. The P1 scribe 170 is a first scribe, the P2 scribe 180 is a second scribe and the P3 scribe 190 is a third scribe.

The soda lime glass substrate 110 has a thickness in the range of approximately 1.0 to 4.0 mms. but is typically 3.2 mms. in thickness. The Mo film 120 is approximately 0.35 microns in thickness. The CIGS film 130 has a thickness in the range of approximately 0.5 to 2.5 microns, but is typically approximately 1.0 micron in thickness. The buffering layer 140 is made of cadmium or zinc sulfide, CdS or ZnS, and is approximately 0.05 micron in thickness. The zinc oxide layer 150 is an intrinsically insulating zinc oxide layer that is approximately 0.1 micron in thickness. The AZO layer 160 is approximately 0.35 micron in thickness and is dependent on an inverse relationship between transmittance and sheet resistance. The total width 195 of the combined scribes P1 170, P2 180 and P3 190 is in the range of approximately 75-150 microns in thickness. The range of thickness however wastes sunlight and reduces a light collecting area that results in a total power loss of approximately 8.7%.

The P1 scribe 170 is produced on the Mo film 120 before the deposition of any remaining films. The CIGS film 130 and buffering layer 140 and zinc oxide layer 150 are then deposited. Scribe P2 180 is then produced from the CIGS film 130, the buffering layer 140 and the zinc oxide layer 150. The AZO layer 160, which serves as a transparent window electrode is then deposited, followed by scribing the P3 scribe 190 to isolate the AZO layer 160 between the P2 scribe 180 and the P3 scribe 190. There are also several subsequent stages of film deposition and scribing which add to the relative complexity and manufacturing time of the solar cell 100.

Details regarding the solar cell 100 are provided in J. Wennerberg, Ph.D. Thesis, Uppsala University, 2002, S. M. Rossnagel and J. Hopwood (IBM Research, Yorktown Heights, N.Y.), Journal of Vacuum Science & Technology B: Microelectronics and Nanometer Structures January 1994, Vol. 12, Iss. I, pages 449-453, U.S. Patent Provisional Application 61/220,577, U.S. Patent Provisional Application 61/220,576 and U.S. Patent Provisional Application 61/292,481.

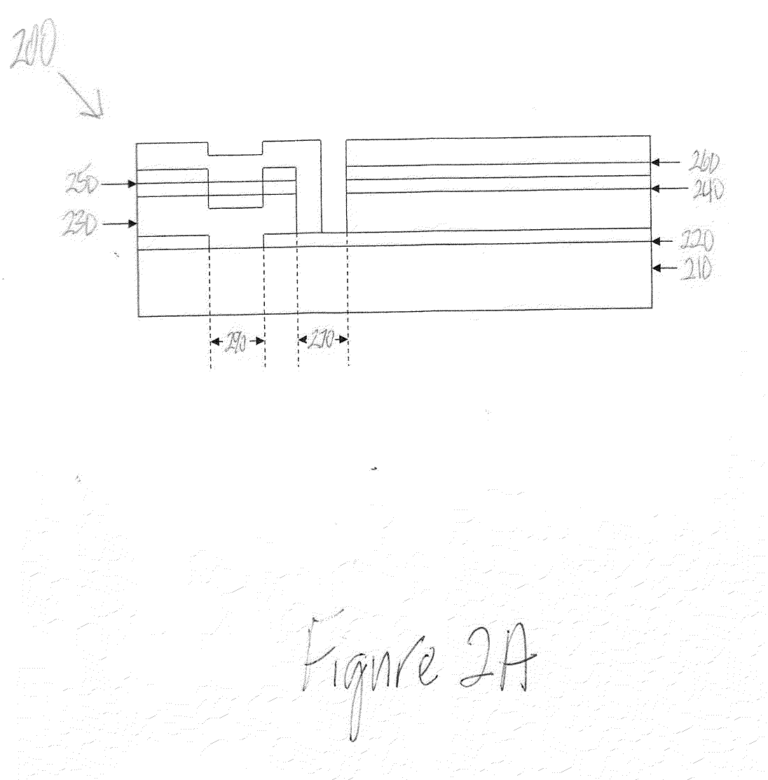

FIG. 2A illustrates a side perspective view of a solar cell 200, in accordance with one embodiment of the present invention. The solar cell 200 includes a soda lime glass substrate 210, a Mo. Film 220, a CIGS film 230, a buffering layer 240 and a zinc oxide layer 250. The thicknesses of the soda lime glass substrate 210, the Mo. film 220, the CIGS film 230, the buffering layer 240 and the zinc oxide layer 250 are the same as illustrated in FIG. 1 and described in its description. Temperature in the range of approximately 450-550° C.° is utilized for depositing the CIGS layer 230 to grow optimal grain size and diffuse sodium from the soda lime glass substrate 110. In one embodiment of the present invention, annealing is than carried out after the CIGS deposition within the same vacuum system.

FIG. 2B illustrates a side perspective view of a solar cell 200, in accordance with one embodiment of the present invention. The solar cell 200 includes a P1 scribe 290 and a P2 scribe 270. The solar cell 200 illustrated in FIG. 2B omits the P2 scribe 280, but includes the deposited P1 scribe 290 and the deposited P2 scribe 270. The P1 scribe 290 and the P2 scribe 270 can be made utilizing lasers, mechanical scribing or etching.

FIG. 2C illustrates a side perspective view of a solar cell 200 that includes a P1 scribe 290 being filled with an insulating layer 292, in accordance with one embodiment of the present invention. The insulating layer 292 can be any suitable insulating layer that is deposited by vacuum deposition to fill the P1 scribe 290.

FIG. 2D illustrates a side perspective view of a solar cell 200 after a conduction layer 294 is deposited directionally into a P2 scribe 270, in accordance with one embodiment of the present invention. The conduction layer 294 which can be AZO or any other suitable conduction layer is deposited obliquely to cover the solar cell 200, while leaving the far wall 298 of the P2 scribe 270 uncovered. The thickness of the insulating layer 294 is kept slightly below the thickness of the solar cell 200. The thickness of the AZO is controlled to exceed the difference in height between the solar cell 200 and the insulating layer 294.

Various methods are possible for the oblique deposition of the conducting electrode AZO layer 260. A method for depositing a zinc metal doped with aluminum layer or Indium tin oxide (ITO) layer is a line of sight vacuum evaporation for metals that can also be utilized in combination with a plurality of directional collimating plates. The zinc oxide doped with aluminum and can be converted to the corresponding oxide by heating, typically by a co-evaporation source.

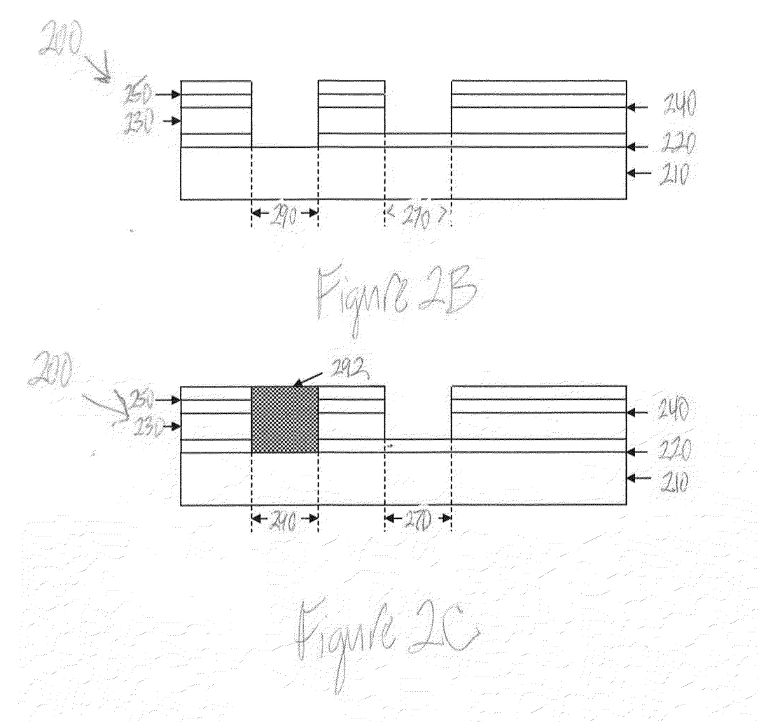

Another method for depositing the AZO layer 260 is collimated sputtering wherein a directional magnetron sputtering method is preferred. Sputtering is generally recognized as less directional, particularly for non magnetron sputtering where gas pressures are higher. An ionized sputtering method can be utilized to impart a charge on neutral sputtered atoms resulting in a deposit that would fall perpendicular to the substrate 210 to ensure coverage between trenches in semiconductors. However, to avoid the need for the P2 scribe 270, the direction of deposition should be at approximately 45 degrees to the vertical when utilizing a set of collimating plates (FIG. 3, 340).

FIG. 3 illustrates a side perspective view of a vacuum chamber 300 receiving deposit conducting material 310 by collimated sputtering in a pass-by mode, in accordance with one embodiment of the present invention. The components of the vacuum chamber 300 are the same as those illustrated and described in FIG. 1 and its descriptions. The collimating plates 340 are shown between the sputtering target 330 and the substrate 350 and insure that the deposited atoms travel in a general direction at an approximate 45 degree angle to the perpendicular. However, the 45 degree angle will also reduce the rate of sputtering up to approximately 66%. Therefore additional sputtering power density is required, which can involve the use of magnetrons, additional sputtering time or a slower pass-by mode. A pulsed DC sputtering method can also be utilized for the previously described methods for depositing AZO described in FIGS. 2C and 2D.

The precise geometry of the collimator plates 340 will depend on the individual sputtering system. Factors affecting the geometry include length, spacing, and proximity of the collimator plates 340 to the substrate 350. A relatively closer distance between the sputtering target 330 and the substrate 350 allows for a greater deposition rate. Typically, this can be in the range of approximately 70-100 mm, so the collimator plates 340 can be up to approximately 35 mm long, separated at approximately 10 mm, angled at 45 degrees to the substrate 350 and be within approximately 15 mm of the substrate 350. For an approximate 70 mm sputtering target 330 to substrate 350 spacing, a deposition shadow of approximately 1-2 microns against a vacuum chamber 300 with an approximate 2 micron thickness is produced. Other suitable combinations of dimensions and angular disposition may be chosen that are consistent with achieving a deposition shadow necessary for electrical isolation.

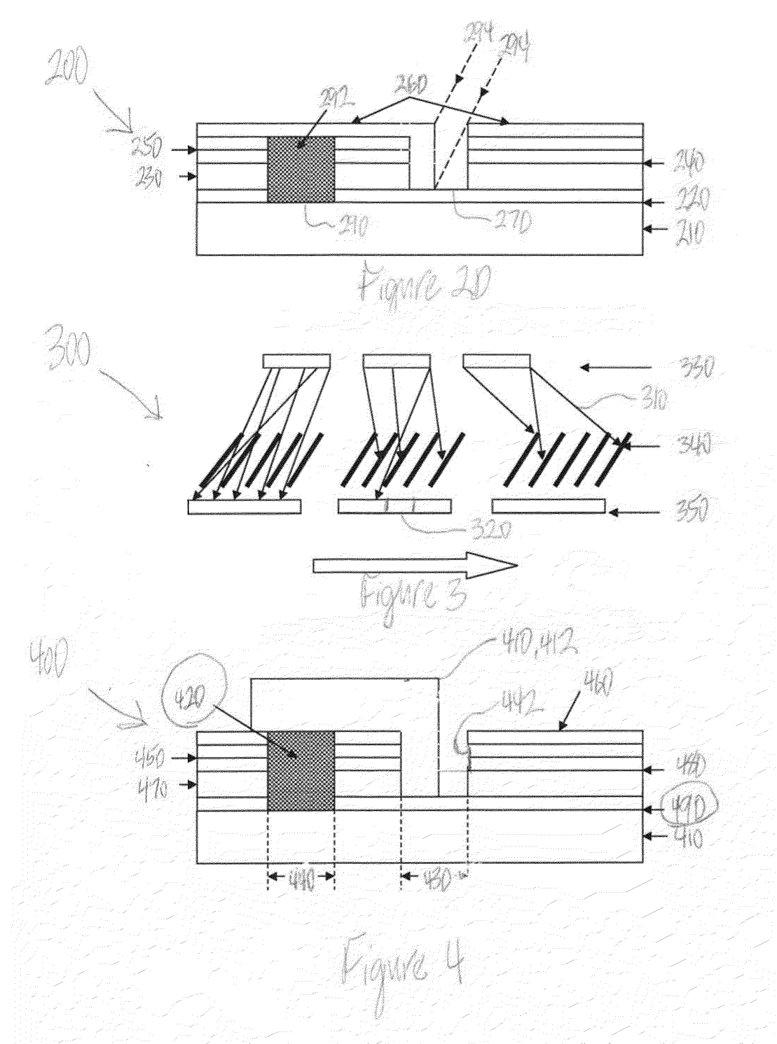

FIG. 4 illustrates a side perspective view of a solar cell 400 with a conductive link 410, in accordance with one embodiment of the present invention. The components of the vacuum chamber 300 are the same as those illustrated and described in FIG. 1 and FIG. 2 and their descriptions. The solar cells 400 include a conductive link 410, an insulating layer 420, a P1 scribe 440, a P2 scribe 430, an i-ZnO layer 450, an AZO layer 460, a CIGS film 470, a buffering layer 480 and the Mo film 490.

The conductive link 410 is a patterned conductor 412 that includes a printed conductive link such as silver or some other metal acting as the connection between one layer of the solar cell 400 and another layer. The conductive link 410 can be utilized between any previously described layers of the solar cell 400. The silver or other metal material is in a powdered form or any other suitable form and is substituted for AZO as the conductive link 410 between the layers. Scribing of the P1 scribe 440 and the P2 scribe 430 is done after all films are deposited, thereby avoiding a break of vacuum between the i-ZnO layer 450 and the i-ZnO film. Grain growth of the CIGS film 470 is done during its deposition by evaporation or sputtering and only a relatively lower temperature anneal is needed after all films are deposited to diffuse zinc and cadmium into the CIGS film 470 to help form a p-n junction. This also avoids a loss of time and materials involved in the collimated sputtering process. A relatively wider separation is achieved between one wall 442 of the P3 scribe 430 and the conductive link 410.

The P1 scribe 440 is filled to the top of the solar cell 400 with the insulating layer 420. A metal link is printed to cover a small portion of the insulating layer 420 on the preceding cell and to cover a significant portion of the P2 scribe 430 without touching the opposite wall 442. Typically, individual scribes can be approximately in the range of 20 to 50 microns by utilizing a laser at the lower end of this range. Therefore the width of the metal link should be in the range of approximately 10-40 microns, with a positional accuracy of approximately less than 10 microns. Alternatively, the P2 scribe 430 can be made wider to accommodate the metal link while narrowing the P1 scribe 440 as much as possible. The metal link could extend up to approximately 200 microns across the insulating layer 420 on the preceding cell without much relative loss, with the cell widths typically being approximately 4-7 mm. Typically, accurate placement of the metal link is important, whereby the metal link does not cover all of the P2 scribe 430 and the deposited conductive link 410 can be up to approximately 35 microns across the width of the P2 scribe 430.

Precision pad printing or ink jet printing are preferred methods of depositing the insulator and metal links to achieve relatively narrow line-widths, accuracy and moderate thickness of deposit in the range of approximately 1-4 microns for the insulating layer 420, but typically in the range of approximately 1.7-2.2 microns. The metal can be relatively thicker in the range of approximately 1-10 microns, but is typically in the range of approximately 3-5 microns. Relatively thicker coatings can be achieved by multiple passes of pad or ink jet printing. The insulating layer 420 and conductive links 410 may also be cured utilizing heat, and/or electromagnetic radiation such as UV light.

Accuracy of registering patterns such as the insulating layer 420 and metal link can be within 0.1 mm for precision ink jet printing, and within 0.01 mm for pad printing. Preferably, the distance between the P1 scribe 440 and the P2 scribe 430 is kept as small as possible to minimize the area between the P1 scribe 440 and the P2 scribe 430 that is unusable for sunlight collection. The metal link particles can be standard colloidal silver utilized for conductively printing conductive tracks, or nanosize conductive materials, such as silver, copper, or carbon nanotubes and oxides, or organic semiconductors compatible with precision printing by ink jet, transfer roll or pad related processes.

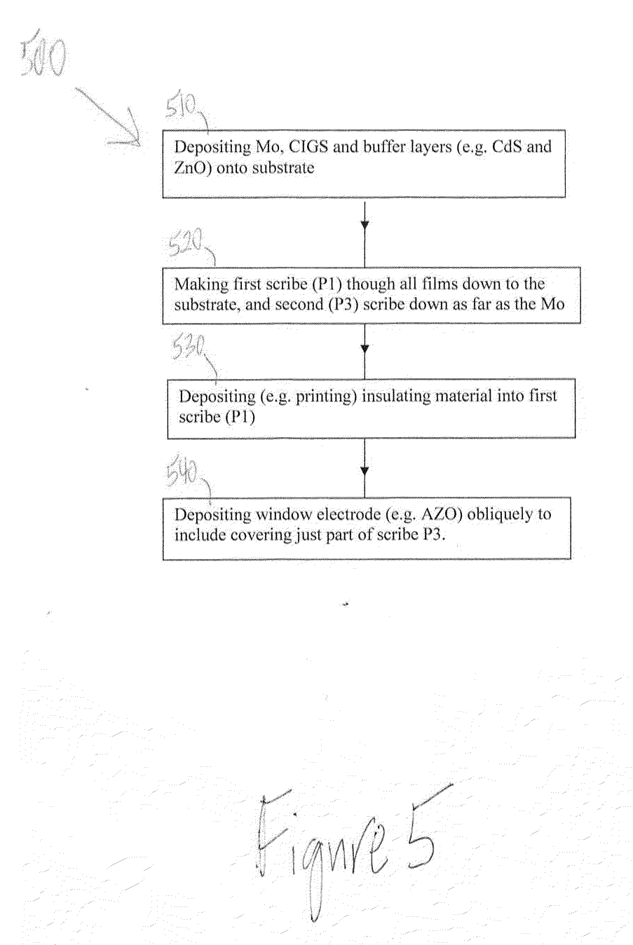

FIG. 5 illustrates a flow chart of a method for scribing 500 a thin film cell that includes a soda lime glass substrate, a film of molybdenum (Mo), a film of copper indium gallium diselenide (GIGS), a buffering layer, a layer of zinc oxide (i-ZnO) or a layer of aluminum doped zinc oxide (n-ZnO:Al or AZO), a first scribe, and a second scribe, in accordance with one embodiment of the present invention.

The method for scribing 500 includes the steps of depositing the Mo film, the CICS film and the buffering layer onto the substrate 510, making the first scribe through the Mo film, the CICS film and the buffering layer 520, making the second scribe onto the Mo layer 530, depositing insulating material into the first scribe 540 and depositing a window electrode obliquely on the solar cell and the second scribe 550.

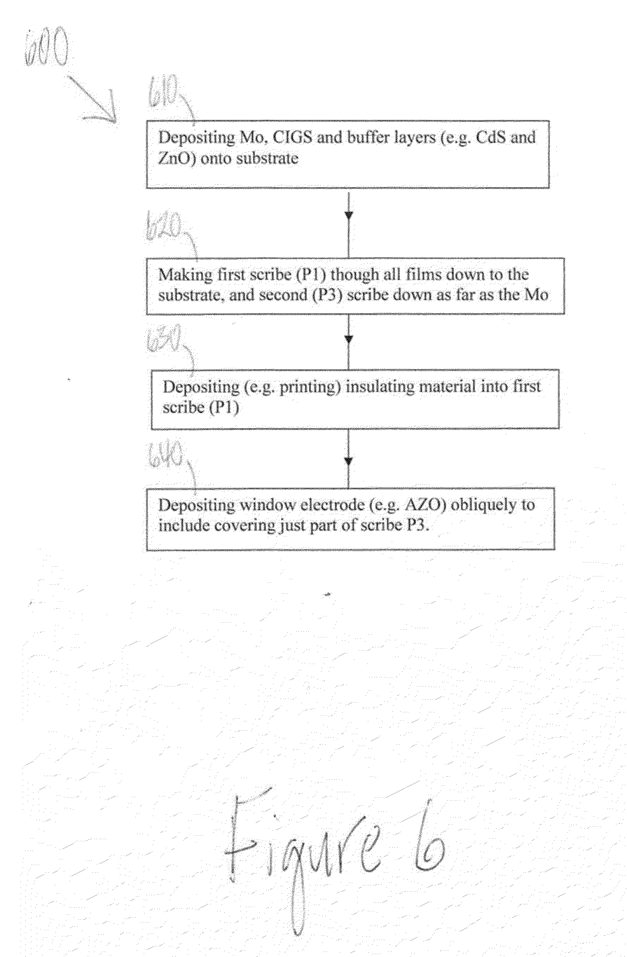

FIG. 6 illustrates a flow chart of a method for receiving 600 a deposited conducting material on a thin film solar cell that includes a soda lime glass substrate, a first scribe to receive said deposited insulating material, a sputtering target and a plurality of collimating plates, in accordance with one embodiment of the present invention. Additional details on the method for receiving are described in FIG. 3 and its description.

The method for receiving 600 includes the steps of depositing said Mo film, said CICS film, said buffering layer, said zinc oxide layer and said insulating layer onto said substrate 610, producing said first scribe on said Mo film 620, producing said second scribe on said CICS film, said zinc oxide layer and said buffering layer above said Mo film 630 and producing said conductive link between desired said layers or said films 640. Additional details on the method for receiving are described in FIG. 3 and its description.

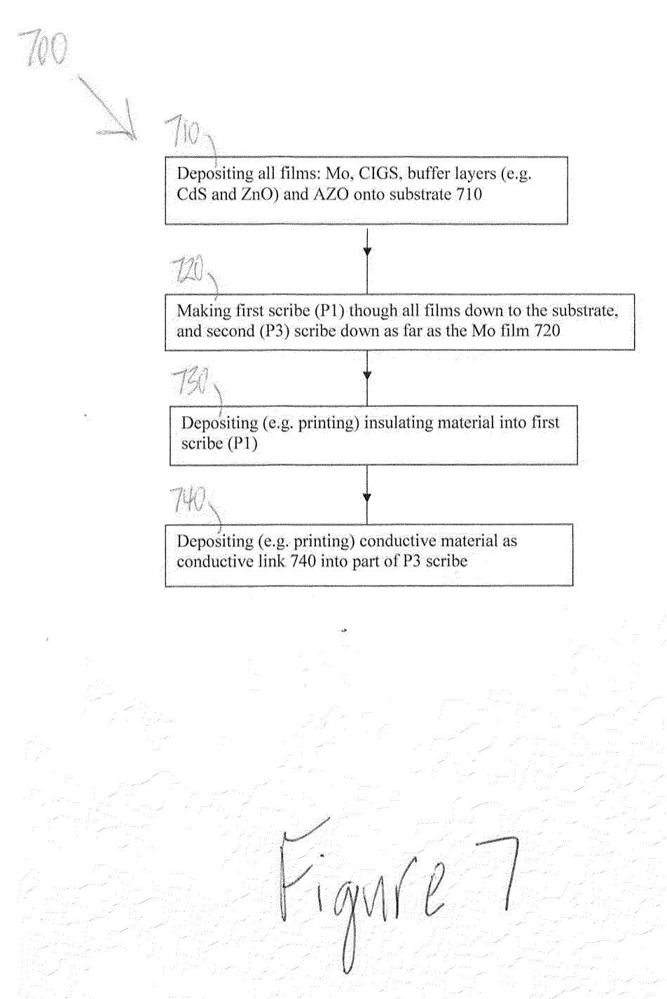

FIG. 7 illustrates a flow chart of a method for scribing 700 a thin film solar cell that includes a soda lime glass substrate, a film of molybdenum (Mo), a film of copper indium gallium diselenide (GIGS), a buffering layer, a layer of zinc oxide (i-ZnO), a layer of aluminum doped zinc oxide (n-ZnO:Al or AZO), an insulating layer, a first scribe, a second scribe and a conductive link between any layers or films, in accordance with one embodiment of the present invention. Additional details on the method for receiving are described in FIG. 4 and its description.

The method for scribing 700 includes the steps of depositing said Mo film, said CICS film, said buffering layer, said zinc oxide layer and said insulating layer onto said substrate 710, producing said first scribe on said Mo film 720, producing said second scribe on said CICS film, said zinc oxide layer and said buffering layer above said Mo film 730 and producing said conductive link between desired said layers or said films 740.

In one embodiment of the present invention, silver, or some other metal, can be deposited by evaporation or laser ablation to utilize shadow masks for photolithography. Preferably, the metal can be deposited utilizing the previously described AZO depositing methods.

In one embodiment of the present invention, the P1 scribe is made immediately after the deposition of Mo and CICS, and any high temperature annealing of the CICS film. The remaining layers and scribes of the solar cell are made, and the insulator and interconnecting AZO or metal layers are deposited by printing or other previously described methods.

In one embodiment of the present invention, a laser can be utilized to deposit the metal interconnection directly by local decomposition of a metal compound, such as silver nitrate, or an organo metallic compound such as a bisbenzene metal in an organic solvent.

In one embodiment of the present invention, the insulator may be a photopolymer or photoresist substance applied to the desired thickness, and cured locally by a UV or a blue laser with a narrow beam to produce the desired line width approximate to the P1 scribe. The polymer may be applied by any suitable method such as dip coating, printing, spinning, or spraying, and excess uncured material is removed with any suitable solvents.

Any conductive material can be considered in place of the metals utilized in the previously described methods such as carbon nanotubes, oxides or conductive polymers. Similarly, the insulator can be of any adequate organic or inorganic material that can be applied by previously described printing methods. Carbon nanotubes or films of graphene may also be substituted for the AZO transparent electrode when a conductor such as a metal conductor is utilized as the conducting link between cells.

The previous methods described are applicable to CIGS thin film solar cells and cells fabricated by other methods. Other methods of manufacture also include flexible thin film solar cells utilizing a flexible conductor as a substrate, such as stainless steel. The previous methods may also be applied to other means of depositing solar cell thin films and solar cell materials other than CIGS.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A thin film solar cell device, comprising:
a soda lime glass substrate;
a film of molybdenum (Mo) disposed on said substrate;
a film of copper indium gallium diselenide (CIGS) disposed on said Mo film;
a buffering layer disposed on said CIGS film;
a layer of zinc oxide (i-ZnO);
a layer of aluminum doped zinc oxide (AZO);
a first scribe made through said Mo film, said CIGS film and said buffering layer;
a second scribe made onto said Mo layer;
an insulating layer and insulating material deposited into said first scribe; and
a window electrode obliquely deposited on said solar cell and said first scribe.

2. The device according to claim 1, wherein said scribes are made by a selected one of the group consisting of a laser, a mechanical scribing method or by an etching method.

3. The device according to claim 1, wherein said insulating material is deposited by printing vacuum deposition into said first scribe.

4. The device according to claim 1, wherein said window electrode is deposited obliquely covering said solar cell and said filled first scribe.

5. The device according to claim 4, wherein said window electrode is selected from the group consisting of AZO, ITO, a plurality of transparent carbon nanotubes or a plurality of nano-size silver wires.

6. The device according to claim 5, wherein said window electrode is deposited into said second scribe.

7. The device according to claim 6, wherein a far wall of said second scribe is uncovered.

8. The device according to claim 7, wherein said window electrode is selected from the group consisting of AZO, ITO, a plurality of transparent carbon nanotubes or a plurality of nano-size silver wires.

9. A method for receiving a deposited conducting material in a vacuum chamber that includes a soda lime glass substrate, a first scribe to receive said deposited conducting material, a sputtering target and a plurality of collimating plates, comprising:
sputtering said conducting material from said sputtering target;
deflecting said sputtered conducting material off said collimating plates; and
receiving said deflected sputtered conducting material onto said substrate.

10. The method according to claim 9, wherein said deflecting is at a 45 degree angle.

11. The method according to claim 9, wherein said sputtering is a collimated sputtering in a pass by mode sputtering method.

12. The method according to claim 9, wherein said sputtering is a pulsed DC sputtering method.

13. A method for scribing a thin film solar cell that includes a soda lime glass substrate, a film of molybdenum (Mo), a film of copper indium gallium diselenide (GIGS), a buffering layer, a layer of zinc oxide (i-ZnO), a layer of aluminum doped zinc oxide (n-ZnO:Al or AZO), an insulating layer, a first scribe, a second scribe, and a conductive link between any said layers or said films, comprising:
depositing said Mo film, said CICS film, said buffering layer, said zinc oxide layer and said insulating layer onto said substrate;
producing said first scribe on said Mo film;
producing said second scribe on said CICS film, said zinc oxide layer and said buffering layer above said Mo film; and
producing said conductive link between desired said layers or said films into part of said second scribe.

14. The method according to claim 13, wherein said scribes are produced by a selected one of the group consisting of a laser, a mechanical scribing method or by an etching method.

15. The method according to claim 15, wherein said insulating layer is deposited into said first scribe by a selected one of the group consisting of a vacuum deposition method, a precision pad printing method or an ink jet printing method.

16. The method according to claim 13, wherein said conductive link is a patterned conductor.

17. The method according to claim 17, wherein said patterned conductor includes a printed conductive link made of silver or copper.

18. The method according to claim 18, wherein said silver is in a powdered form.

19. The method according to claim 13, wherein said conductive link and said insulating layer are cured by heat or electromagnetic radiation.

20. The method according to claim 13, wherein said magnetic radiation is UV light.
